(19) United States
(12) Patent Application Publication
(10) Pub. No.: US 2003/0138118 A1
(43) Pub. Date: Jul. 24, 2003

(54) Method for control of a unit comprising an acoustic output device

(76) Inventor: Volker Stahl, Aachen (DE)

Correspondence Address: Corporate Patent Counsel, Philips Electronics North America Corporation, 580 White Plains Road, Tarrytown, NY, 10591, US

(21) Appl. No.: 10/240,592

(22) PCT Filed: Nov. 19, 2001
(86) PCT No.: PCT/EP01/13468

(30) Foreign Application Priority Data
Nov. 27, 2000 (DE) 100 58 786.0

(51) Int. Cl. H03G 3/00

(52) U.S. Cl. 381/107; 381/104

(57) ABSTRACT

The invention relates to a method of controlling a device (1) comprising an acoustic output means (2) by means of acoustic command signals (BS). The invention proposes that the device (1) automatically reduce its volume if the device (1) recognizes that an acoustic command signal has been sent to the device (1).

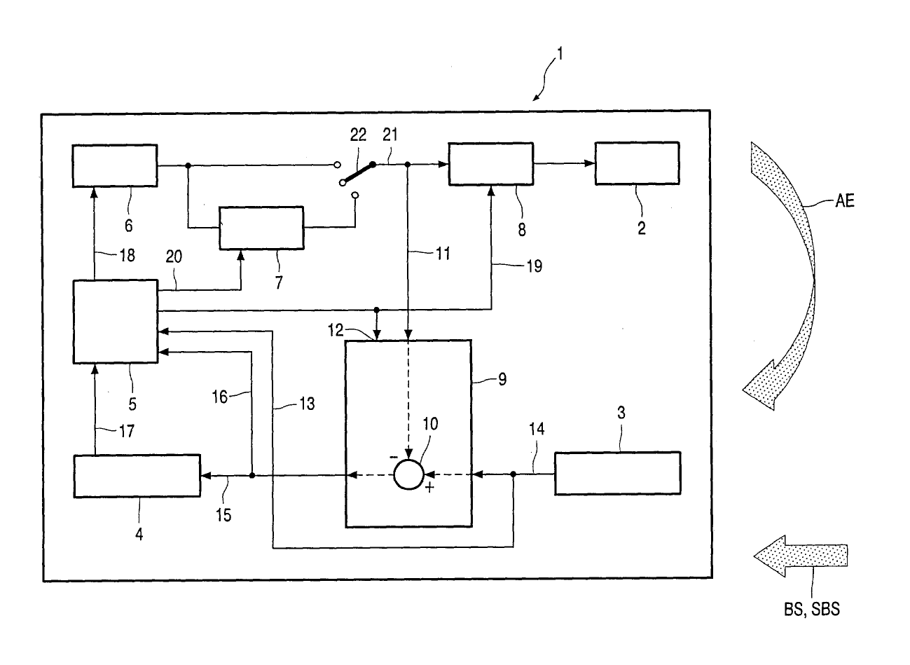

The invention relates to a method of controlling a device comprising an acoustic output means by means of acoustic command signals. The invention additionally relates to a device having an acoustic output means, a receiving means for receiving command signals, a recognition means for recognizing these command signals and a control means for controlling the device as a function of a recognized command signal.

To increase the user-friendliness and options for use of devices, in particular devices in the field of consumer electronics and thus to make the devices more attractive, an ever increasing number of devices are so equipped that control of the device is possible by means of acoustic command signals. For instance, switchable devices, such as for example alarm clocks or lamps, have long been available on the market which may be switched on and off or switched between different modes by means of very simple acoustic command signals, for example sounds such as clapping or whistling. As speech recognition systems develop, devices have also become available which may recognize and accept various voice commands as command signals, so that complicated control of such devices is also possible. Such voice-controllable devices are highly convenient, since the operator may operate the respective device without having to use his/her hands. This control method consequently has considerable advantages wherever the operator needs his/her hands for other activities, for instance in the case of control of a car radio, where the operator must not take his/her hands off the steering wheel to change the volume or the channel. In addition, this method is also more generally attractive with regard to device operation, because such voice control enables the man-machine interface (MMI) to be shifted from the hitherto conventional plane of communication with machines, namely operation by buttons and controllers, to the communication plane normal to humans, namely information transfer via speech. However, a problem arises with the control of devices that comprise an acoustic output means and by virtue of their function themselves produce acoustic signals, i.e. for example all audio or audiovisual devices such as radios, CD players, televisions, video players, computers etc. With such devices with an audio function, the recognition means designed to identify the command signals receives not only the command signal but also the acoustic output signal produced by the device itself (for example the music played on a CD player) as an acoustic echo. The device's own output signal consequently lies beneath the command signal in the manner of background noise. Depending on the volume of the command signal or the device's own output signal, this may lead to considerable problems in recognizing the command signals.

The so-called “AEC method” (Acoustic Echo Cancellation) is conventionally used to improve the recognition performance of such devices. With this approach, the output signal generated by the device itself is used to estimate a room impulse response signal, i.e. to estimate the signal which is detected again by the pick-up means due to reflection of the output signal within the room in which the device is located. This is effected by a so-called “adaptive filter method”, in which a transfer function is determined iteratively, with which the original output signal is initially transformed and then the thus transformed output signal is removed from the received overall input signal in a filter. The method is adaptive to the extent that the iteration method continues permanently and thus changes in the room are detected which are accompanied by a change in transfer function. For example, changes in the acoustic echo could arise if curtains are opened or closed within the room, a door is opened or people move about inside the room. In general, this method is quite successful. However, it has been observed that the accuracy of speech recognition systems reduces significantly if the volume of the output signal of the device itself increases. The reason for this is that the adaptive AEC filter cannot model the room characteristics optimally and therefore the interference of the signal after filtering-out of the acoustic echo is approximately proportional to the volume of the device itself.

It is an object of the present invention to provide a simple, user-friendly method for acoustic control of devices which themselves produce an acoustic output signal, and a corresponding device, in which the recognition accuracy of the command signals is improved relative to the prior art.

Said object is achieved by a method as claimed in claim 1 and a device as claimed in claim 10.

According to the invention, the volume is reduced immediately by the device itself as soon as the device recognizes that a possible acoustic command signal is being sent to the device. By automatically reducing the volume of the device, the command signal for the device may be more easily and reliably recognized due to the smaller acoustic echo. In addition, it is usually more agreeable for the user to utter a voice command when the audio device is not so loud. Moreover, the so-called “Lombard effect” is also reduced by the reduction of the volume, said effect meaning that a person automatically speaks differently, for example more loudly and with more careful enunciation, when he/she has to speak against background noise, which necessarily has effects on the recognition performance of a speech recognition system.

An appropriate device according to the invention has to comprise firstly an acoustic output means, a receiving means for receiving the acoustic command signals, for example a conventional microphone, as well as a recognition means for recognizing these command signals and a control means for controlling the device as a function of a recognized command signal. Moreover, the device must comprise suitable means for recognizing that the receiving means is receiving a possible command signal for the device, together with suitable means with which the volume of the output signal output by the acoustic output means is reduced as soon as the reception of a possible command signal for the device is recognized.

This recognition that a command signal has been directed at the device may be performed in various ways. For example, the device may be so equipped or adjusted that a word spoken by a given user at a defined volume and/or pitch and/or speech direction is recognized as a possible command signal and the volume is then reduced.

In a particularly simple, preferred embodiment, a key command signal is sent before the command signal proper, the volume being reduced when said key command signal is recognized. It is sensible for this key command signal to be the very command signal which adjusts the device into a state of readiness for receiving further command signals, i.e. which initially activates the control means of the respective device. Such “activation signals” are necessary anyway in many cases, since it is in this way possible to prevent command signals output unintentionally by the user, for example particular words within a conversation or other background noises, from being identified and accepted by the device and thus performing a control action which is not actually desired. In particular, such key command signals are sensible if a plurality of voice-controllable devices are present in the same area which in each case accept similar or identical command signals. In this case, the device for which a particular command signal is intended has to be addressed with an appropriate prior key command signal. Thus, for example, a voice-controlled computer and a television could be arranged immediately next to one another, the command signals for the devices being preceded by the key command signal “computer” or “TV” respectively.

Automatic reduction of the volume of the output signal of the device upon recognition of the key command signal also has the advantage that the user is thereby informed at the same time that the respective device is in a state of readiness for receiving further command signals and is so to speak “listening” to the user. The device may optionally also additionally output visual or acoustic confirmation of reception of the key command signal.

Volume reduction is preferably effected again automatically after a command signal—for example following the key command—has been recognized. This means, for example, that a command signal is accepted just after each key command signal. It is alternatively possible for the volume to be automatically readjusted to the previously set value after a certain interval after recognition of the key command signal or a command signal. In this case, the device would wait a certain time after reception of a command signal, to see whether it was to be followed by a further command signal. Only then would the device be automatically switched back out of the state of readiness or activated state.

In the case of a particularly preferred example of embodiment, the volume of the output signal is reduced as a function of a detected command signal energy. Command signal energy is understood to mean the signal energy of the received command signals, wherein the key command signal is naturally also to be understood in this sense as a (special) command signal. Thus, for example, the volume of the device's own output signal could be reduced only when the device's own output signal is actually so loud in relation to the command signals that reliable recognition of the command signals may no longer be ensured. This may be simply controlled in that the ratio between the output signal energy or the signal energy of the determined or estimated acoustic echo of the output signal and the command signal energy is determined. Only if this ratio lies within a particular value range relative to a predetermined threshold is the volume reduced. For example, if the ratio of the energy of the output signal or the acoustic echo to the command signal energy is determined, the volume is reduced only when this ratio lies above a predetermined threshold. Conversely, if the ratio of the energy of the command signal energy to the output signal energy or the energy of the acoustic echo is determined, the volume is reduced only when this ratio lies below a predetermined threshold. The command signal energy may be measured for example at the input of the receiving means or the microphone.

In the case of a particularly preferred method, the volume of the output signal is reduced precisely until the ratio of the signal energies is at a predetermined value. For the user this means that, when the acoustic signal output by the device itself, for example the music from a CD player, is quiet anyway or when the user is very close to the microphone of the device, the music volume is not reduced, but rather remains unchanged. Otherwise, the volume is reduced until the music energy and the energy of the voice command at the microphone inlet are in a predetermined ratio. This ratio may be previously defined and set by the user or it may also be automatically defined in that a given recognition reliability of the recognition means is achieved.

In this case in particular it is sensible for the device to comprise additional means for visual or acoustic display, which display that the key command signal has been recognized, since the user cannot always rely on the fact that the volume will be reduced after recognition of the key command signal.

The device preferably additionally comprises a filter means for filtering out an acoustic echo of the output signal output by the device itself from the overall signal received by the device, i.e. the novel method is used in addition to an AEC method, thereby to achieve optimum recognition performance.

Typical voice commands used to control audio devices or audiovisual devices are command words for controlling the volume of the device. These “volume command signals” may comprise, for example, the words “louder” or “quieter”. Since, according to the invention, the volume is reduced by the device immediately after recognition of the key command signal, the user may no longer recognize what effect his/her volume command signal itself has. For such volume command signals, therefore, after recognition of such a volume command signal the device itself preferably initially returns the volume to the value set prior to the reduction. Only then is the volume set to a value corresponding to the volume command signal, i.e., when the word “quieter” is recognized, for example, the volume is reduced by a given degree or, when the word “louder” is recognized, it is increased by a given degree.

The invention will be further described with reference to an example of embodiment shown in the drawings to which, however, the invention is not restricted.

The single FIGURE shows a schematic block diagram of an audio device 1, for example a CD player, wherein only the components essential to the invention are shown.

The audio device 1 firstly comprises an audio signal source 6. In the case of a CD player for example, this audio signal source 6 is the CD drive, the sampling means and the electronics for converting the detected optical data into the audio signal. The audio signal produced by the audio signal source 6 is then fed to an amplifier 8, for example a conventional output stage 8, and thence is output via an acoustic output means 2, here a conventional loudspeaker 2.

For control purposes, the device 1 comprises a control means 5, which may take the form of a microcontroller or the like, for example. By means of this control means 5, the audio signal source 6 may be actuated, for example a particular track on a CD may be selected. This control possibility is indicated in the FIGURE by the illustrated control lead 18. Similarly, the volume of the device 1 may be adjusted via the control means 5. This is achieved by actuation of the output stage 8. This control possibility is shown in the FIGURE by the control lead 19.

The control commands are received by the device 1 in the form of acoustic command signals BS, voice commands here, which the user inputs via a pick-up means 3, a microphone 3 here, and which are fed to a recognition means 4, a speech recognition system 4 here, via the leads 14, 15. The recognized command is then fed to the control means 5 via the signal lead 17, which control means 5 then controls the individual components of the device 1 in accordance with the command received.

As the FIGURE shows, the microphone 3 picks up not only the command signal BS but also an acoustic echo AE, which is produced by the acoustic signal output by the loudspeaker 2 of the device 1 itself, here the music from the CD. The acoustic echo AE depends not only on the output signal but also on the acoustic parameters of the room. To reduce the interference caused by this acoustic echo AE during recognition of the command signals BS, the device comprises a filter means 9 (designated below as AEC unit), in which the acoustic echo AE is filtered out of the overall signal received by the microphone 3.

To this end, the output signal is tapped from the signal output branch, which extends from the audio signal source 6 via the output stage 8 to the loudspeaker 2, prior to the output stage 8 at the tapping point 21 and fed via a signal lead 11 to the AEC unit 9, which transforms the tapped output signal by a transfer function. This transfer function corresponds to the estimated room impulse response. The respective current room impulse response is determined by an iterative method, wherein updating is effected constantly and thus adaptive filtering is performed which takes account of changes in the room, for example movements of people or objects. The output signal transformed by means of the transfer function is removed from the overall signal coming from the microphone 3 via the signal lead 14 in an adder 10 of the AEC unit 9. Via the output lead 15, the residual signal, which ideally corresponds only to the command signal BS, is then fed from the AEC unit 9 to the speech recognition system 4. The AEC means 9 additionally comprises an input 12, at which the control signal output to the output stage 8 by the control means 5 via the control lead 19 is applied for adjusting the volume. The coefficients for the transfer function may thus be scaled in the AEC unit 9 in accordance with the set volume.

According to the invention, the device 1 additionally comprises means 7 in the form of an attenuator 7, with which the volume of the device 1 may be reduced if a key command signal SBS is recognized by the speech recognition system 4. In the present example of embodiment, this key command signal SBS has therefore to be uttered by the user as a first command signal. The speech recognition system 4 is so designed that it merely waits for this special key command signal SBS, i.e. for a particular key word such as for example the word “CD”. Once this key word has been accepted, the entire complex command vocabulary of the speech recognition system 4 is then activated and the device 1 is in a readiness mode, in which further command signals are recognized and accepted, for example commands such as “louder”, “quieter”, “next track”, “track 5” etc. Once the respective command signal BS following the key command signal SBS has been recognized, the device 1 switches back to a state in which it is again awaiting the key command signal SBS.

Upon recognition of the key command signal SBS, the attenuator 7 is automatically activated according to the invention by the control means 5 via the control lead 20 and thus the volume of the device's 1 own output signal is reduced. In this way, the subsequent command signal BS, i.e. the command proper, is easier for the speech recognition system 4 to identify. The volume may be reduced for example by a certain value, e.g. 10 dB, or to a preset volume level. It is also possible to reduce the volume right down to zero.

In the example of embodiment shown in the FIGURE, however, the signals applied to the signal input branch up- and downstream of the filter 10 are fed via the signal leads 13, 16 to the control means 5. From these signals up and downstream of the filter 10, it is possible for the control means 5 to determine what signal energy the acoustic echo AE exhibits at the microphone and what signal energy is exhibited by the actually desired command signal BS. The control means 5 is so designed that it reduces the volume of the output signal by means of the attenuator 7 until a given ratio between the signal energy of the acoustic echo AE and the signal energy of the command signal BS is achieved. If the ratio of the signal energies is already below this value, the volume is not reduced any further, i.e. the music volume is not reduced any more when the music is quiet anyway or when the user is close to the microphone and the command signals BS are easy to recognize. Otherwise, the music volume is reduced precisely enough for the energy of the music and the energy of the voice commands at the microphone inlet to be in a predetermined ratio.

By means of a simple switch 22, the attenuator 7 in the signal output branch may be by-passed in the example of embodiment shown, so allowing the user to deactivate the function according to the invention should he/she so desire.

The separate attenuator 7 is arranged here in the signal output branch so that the signal is attenuated prior to the spur point 21 for tapping of the output signal for the AEC unit 9. In this way, account is automatically taken of the fact that, in the event of a reduction in volume, the AEC unit 9 takes account of this volume reduction when estimating the room impulse response. A reduction in the volume of the output signal of the device 1 without account being taken thereof in the AEC unit 9 would lead to additional interference due to filtering in the filter 10 and would tend rather to hinder recognition of the command signal BS.

Instead of the separate attenuator 7, the volume of the control means 5 could also be reduced after recognition of the key command signal SBS by adjustment of the output stage 8.

In the case of the device 1 according to the invention or through the method according to the invention, the accuracy of recognition of the voice control is improved considerably by reducing distortion of the input signal of the speech recognition system. A very user-friendly speech interface is provided, since the user receives an acknowledgement from the device 1 in the form of the reduction in volume that said device 1 is ready for a voice command. An additional acknowledgement may optionally follow in the form of a visual or further acoustic signal, for example a signal tone.

1. A method of controlling a device (1) comprising an acoustic output means (2) by means of acoustic command signals (BS), characterized in that, as soon as the device (1) recognizes that an acoustic command signal is being sent to the device (1), the volume of the output signal output by the acoustic output means (2) is reduced.

2. A method as claimed in claim 1, characterized in that first of all an acoustic key command signal (SBS) is sent to the device (1), by means of which the device (1) is brought to a state of readiness to receive further command signals (BS) and, upon recognition of this key command signal (SBS) by the device (1), the volume of the output signal output by the acoustic output means (2) is reduced.

3. A method as claimed in claim 1 or claim 2, characterized in that the volume of the output signal is reduced as a function of a determined command signal energy.

4. A method as claimed in claim 3, characterized in that the volume of the output signal is reduced only if the ratio between a determined output signal energy or a signal energy of a determined acoustic echo (AE) of the output signal and the command signal energy lies in a particular value range relative to a predetermined threshold.

5. A method as claimed in claim 4, characterized in that the volume of the output signal is reduced until the ratio between the output signal energy or the signal energy of the acoustic echo (AE) of the output signal and the command signal energy corresponds to a predetermined value.

6. A method as claimed in one of claims 1 to 5, characterized in that, after recognition of a command signal (BS) following the key command signal (SBS), the volume is readjusted to the value set prior to the reduction.

7. A method as claimed in one of claims 1 to 6, characterized in that the volume is readjusted to the value set prior to reduction after a certain interval has passed after recognition of a key command signal (SBS) or a command signal (BS).

8. A method as claimed in one of claims 1 to 7, characterized in that, after recognition of a volume command signal, which is sent to change the volume, the volume is initially readjusted to the value set prior to reduction and then adjusted to a value corresponding to the volume command signal.

9. A method as claimed in one of claims 1 to 8, characterized in that recognition of the key command signal is displayed visually or acoustically to a user of the device.

10. A device (1) having an acoustic output means (2), a receiving means (3) for receiving acoustic command signals (BS), a recognition means (4) for recognizing these command signals (BS) and a control means (5) for controlling the device (1) as a function of a recognized command signal (BS), characterized by means for recognizing that the receiving means (3) is receiving a command signal (BS) for the device (1), and means (7) for reducing the volume of the output signal output by the acoustic output means (2) as soon as reception of a possible command signal (BS) for the device (1) is recognized.

11. A device as claimed in claim 10, characterized in that the means for recognizing that the receiving means (3) is receiving a command signal (BS) for the device (1) comprise means for recognizing a key command signal (SBS), by means of which the device (1) is brought into a state of readiness to receive further command signals (BS).

12. A device as claimed in claim 10 or claim 11, characterized by a filter means (9) for filtering out an acoustic echo (AE) of the output signal output by the device (1) itself from the overall signal received by the receiving means (3).

13. A device as claimed in claim 12, characterized in that the means (7) for reducing the output signal of a branch point of the device are arranged upstream of a tapping point (21) at which a signal corresponding to the output signal is tapped for the filter means (9).

14. A device as claimed in claim 12 or claim 13, characterized in that the filter means (9) comprises an input (12) for transmitting a control command for reducing the volume of the output signal of the device (1).

15. A device as claimed in one of claims 10 to 14, characterized by means (5, 13, 16) for determining the ratio between the signal energy of the output signal and/or the acoustic echo (AE) of the output signal and the signal energy of the command signal (BS).
